(19) United States
(12) Patent Application Publication
(10) Pub. No.: US 2008/0137399 A1
(43) Pub. Date: Jun. 12, 2008

(54) Single Chip Having Magnetoresistive Memory

(76) Inventors: Chien-Chiang Chan, Taipei Hsien (TW); James Chyi Lai, Saint Paul, MN (US)

Correspondence Address: THOMAS, KAYDEN, HORSTEMEYER & RISLEY, LLP, 600 GALLERIA PARKWAY, S.E., STE 1500, ATLANTA, GA, 30339-5994, US

(21) Appl. No.: 11/814,524

(22) PCT Filed: Jan. 25, 2005
(86) PCT No.: PCT/US05/02289

§ 371 Date: Jul. 23, 2007

(51) Int. Cl. G11C 11/00; G11C 11/14

(52) U.S. Cl. 365/158; 365/173

(57) ABSTRACT

A single chip has a substrate and at least one magnetoresistive memory layer. The substrate has an underlying memory and a control circuit. The magnetoresistive memory layer is placed on the substrate, and has a plurality of magnetoresistive random access memory cells controlled by the control circuit.

### BACKGROUND

1. Field of Invention

The present invention relates to a single chip. More particularly, the present invention relates to a single chip having magnetoresistive memory.

2. Description of Related Art

System-on-chip (SOC) products are widely used with the developments of semiconductor techniques. An SOC generally has logic circuits and an embedded non-volatile memory, such as EPROM, EEPROM, FLASH memory or FeROM. FIG. 1 is a schematic view of a conventional SOC chip. As illustrated in FIG. 1, a SOC chip 100 has logic circuits 102 and embedded memories 104. The logic circuits 102 include a microprocessor 112 and a control circuit 122 for memories. In the SOC chip 100, the embedded memories 104 are placed in the same plane as the logic circuits, and may have more than one type for different functions. For example, the embedded memories 104 may include a ROM 114, a RAM 124 and a FLASH memory 134.

Generally, the logic circuits 102 sit on a p-substrate, and the embedded memories 104 sit on an n-well in the p-substrate. The traditional manufacturing process requires additional steps for creating n-wells in the p-substrate. Moreover, the embedded memories 104 are typically laid out adjacent to the logic circuits 102, and thus consume precious silicon area. For example, the embedded memories 104 on a SOC today typically occupy 20-70% of the die size. Thus, the conventional SOC chip leads to a very low yield, a low total number of SOC chips per wafer, and therefore high costs.

### SUMMARY

It is therefore an aspect of the present invention to provide a single chip having a magnetoresistive memory, which dominates embedded memory applications requiring embedded volatile and/or non-volatile memory, like ROM, SRAM, EEPROM, DRAM, FLASH memory or other embedded memories.

According to one preferred embodiment of the present invention, the single chip comprises a substrate and at least one magnetoresistive memory layer. The substrate comprises an underlying memory and a control circuit. The magnetoresistive memory layer is placed on the substrate, and comprises a plurality of magnetoresistive random access memory cells controlled by the control circuit.

It is another aspect of the present invention to provide a single chip having a magnetoresistive memory, in which a magnetoresistive memory layer is on a substrate having logic circuits. The single chip simplifies the manufacturing process, decreases chip size and increases memory size, thus reducing the manufacturing cost.

According to another preferred embodiment of the present invention, the single chip comprises a substrate and at least one magnetoresistive memory layer. The substrate comprises a plurality of logic circuits and a control circuit. The magnetoresistive memory layer is placed on the substrate, and comprises a plurality of magnetoresistive random access memory cells controlled by the control circuit.

It is to be understood that both the foregoing general description and the following detailed description are examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a schematic view of a conventional SOC chip;

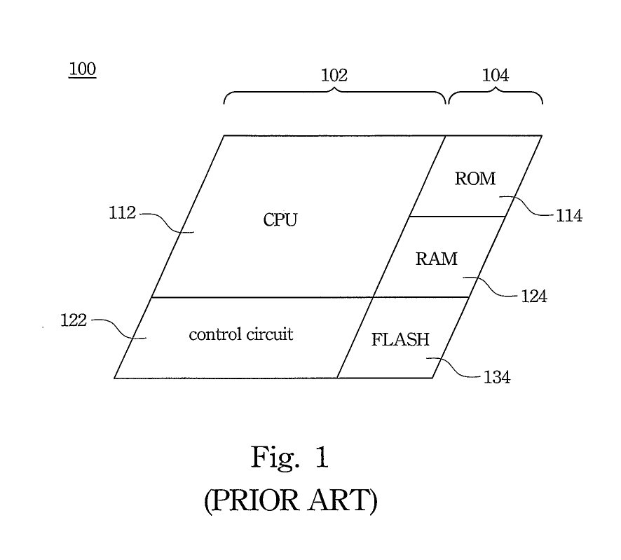

FIG. 2A is a schematic view of one preferred embodiment of the present invention;

FIG. 2B illustrates a functional block diagram according to a first example;

FIG. 2C illustrates a functional block diagram according to a second example;

FIG. 3 illustrates a schematic view of one preferred embodiment, of which the electronic elements are embedded in the logic circuit; and

FIG. 4 illustrates a schematic view of one preferred embodiment, of which the magnetoresistive memory layer comprises more than one layer.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

Magnetoresistive random access memory (MRAM) is a type of non-volatile memory with fast programming time and high density. The MRAM architecture includes a plurality of MRAM, cells and intersections of word lines and bit lines. A MRAM cell includes two ferromagnetic layers separated by a non-magnetic layer. Information is stored as directions of magnetization vectors in the two ferromagnetic layers.

The resistance of the non-magnetic layer between the two ferromagnetic layers indicates a minimum value when the magnetization vectors of the two ferromagnetic layers point in substantially the same direction. On the other hand, the resistance of the non-magnetic layer between the two ferromagnetic layers indicates a maximum value when the magnetization vectors of the two ferromagnetic layers point in substantially opposite directions. Accordingly, a detection of changes in resistance allows information being stored in the MRAM cells. More particularly, embedded MRAM designs of 1 Kb, 64 Kb, 1 Mb or more Mb are available, and have similar performances as a standalone MRAM IC.

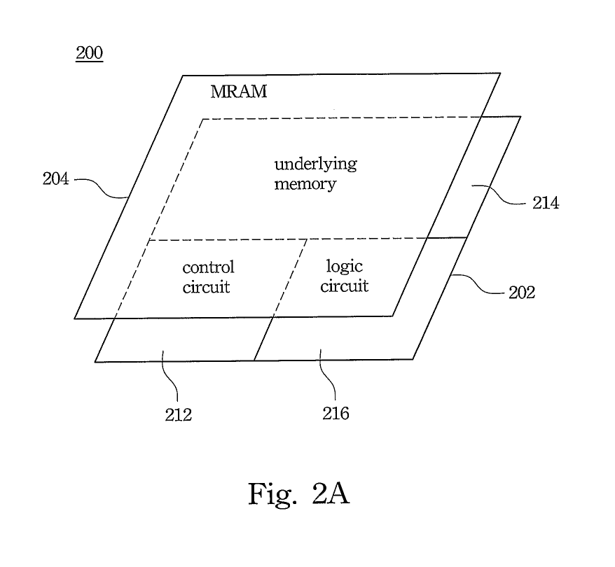

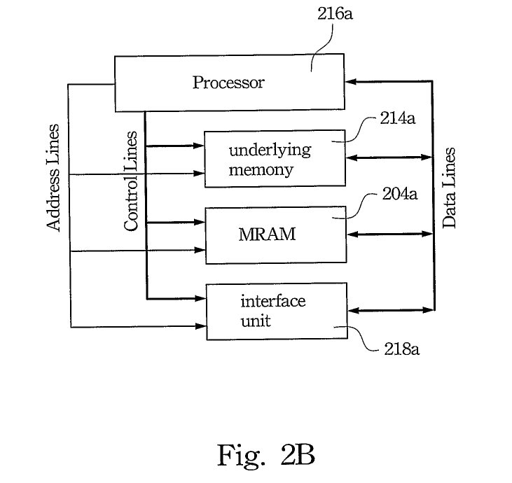

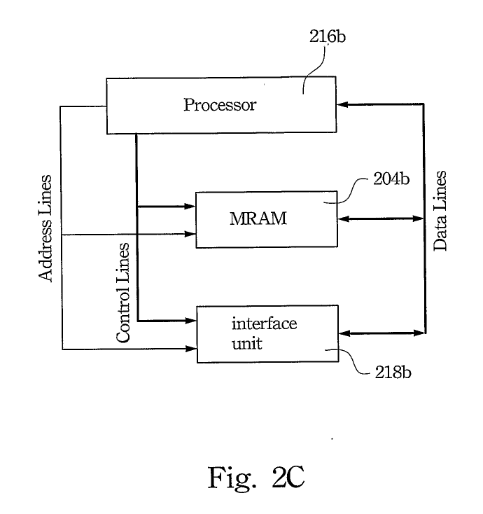

FIG. 2A is a schematic view of one preferred embodiment of the present invention. A single chip 200 comprises a substrate 202 and a magnetoresistive memory layer 204. The substrate 202 comprises an underlying memory 214 and a control circuit 212. The magnetoresistive memory layer 204 is placed on the substrate 202, and comprises a plurality of MRAM cells (not shown). The control circuit 212 is positioned in the substrate 202 for controlling the MRAM cells of the overlaying magnetoresistive memory layer 204.

The substrate 202 is silicon, GaAs or other material used in semiconductor technology, and contains CMOS or Bipolars thereon. The underlying memory 214 is a volatile or non-volatile memory, or both. For example, the volatile memory is DRAM or SRAM, and the non-volatile memory is EPROM, EEPROM, FLASH or FeRAM. Because MRAM is as fast as SRAM, as non-volatile as FLASH memory and as high-density as DRAM, the underlying memory 214 can be designed to cooperate with the overlaying magnetoresistive memory layer 204 for providing a complementary and excellent memory function in the single chip 200.

The substrate 202 further comprises a logic circuit 216, such as a microprocessor, a RFID circuit or an ASIC circuitry. Two examples are used to illustrate the functional interactions among the logic circuit 216, the MRAM of the overlaying magnetoresistive memory layer 204 and the underlying memory 214. In the two examples, the logic circuit 216 is a microprocessor, a RFID circuit or an ASIC circuitry, and is denoted as Processor in FIGS. 2B and 2C.

FIG. 2B illustrates a functional block diagram according to a first example. As illustrated in FIG. 2B, a processor 216a, an underlying memory 214a, a MRAM 204a and an interface unit 218a are electrically connected by address, control and data lines. The MRAM 204a is used to store system initiation information. With this configuration, control instructions can be updated and corrected after product designed. Moreover, data stored in the single chip is reserved when power is not supplied, and a product having the single chip installed therein can be instant-boot. That is, the product can be instantly usable right after power thereto is turned on.

The underlying memory 214a and the MRAM 204a are used to provide similar or different functions for the processor 216a. For instance, when the underlying memory 214a is a non-volatile memory with slow speed and high storage, the MRAM 204 can be a storage buffer of the underlying memory 214a. Alternatively, when the underlying memory 214a is a volatile SRAM, the MRAM 204a can be a long-lasting nonvolatile memory. Furthermore, the functions of the underlying memory 214a and the MRAM 204a can be similar and are adjustable by the user.

FIG. 2C illustrates a functional block diagram according to a second example. As illustrated in FIG. 2C, a processor 216b, a MRAM 204b and an interface unit 218b are electrically connected by address, control and data lines. The second example illustrates that the MRAM 204b is the only system memory source along with developments and improvements of MRAM technology. When the speed, design and power of the MRAM 204b are improved to fit requirements, the MRAM 204b completely replaces the underlying memory 214a used in the first example. Therefore, specialized processor types or functions may be developed to take advantages of fast and non-volatile features of the MRAM 204b.

The control circuit 212 in FIG. 2A comprises a plurality of electronic elements for controlling the cells of the magnetoresistive memory layer 204. Only one transistor is typically required for 32 or more bits of MRAM. Therefore, only 2 or 3 metal layers are needed for constructing the circuit made of the transistors and the MRAM cells, and the manufacturing processes are thus simplified.

Moreover, the electronic elements can be positioned within a region of the substrate 202. Alternatively, some or all of the electronic elements can be embedded in the logic circuits 216, such as a microprocessor, a RFID circuit or an ASIC circuitry. That is, the electronic elements of the control circuit 212 can be physically gathered in a certain region or distributed over the substrate 202. In other words, the electronic elements of the control circuit 212 can be prepared alone and only for MRAM or can be shared with other circuits of the substrate 202.

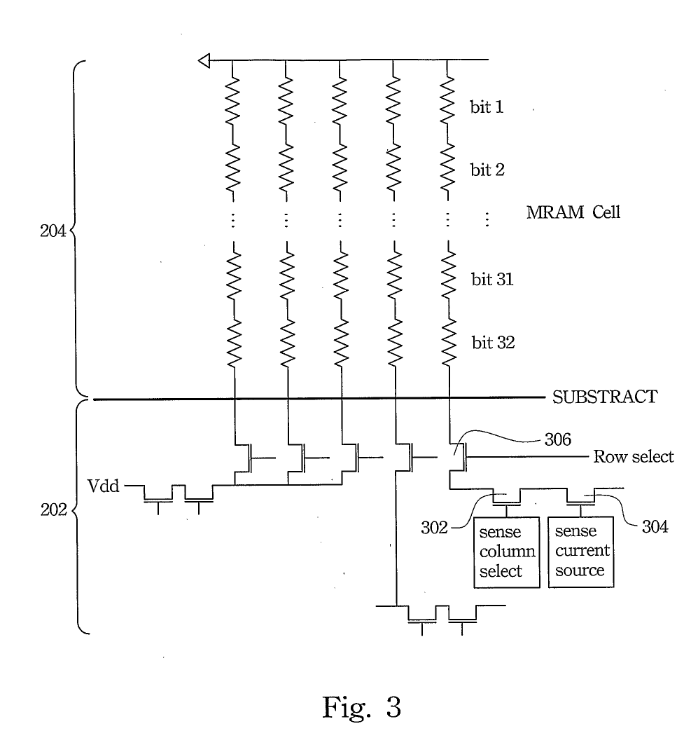

FIG. 3 illustrates a schematic view of one preferred embodiment of which the electronic elements are embedded in the logic circuit 216. As illustrated in FIG. 3, a transistor 306 is required for 32 or more bits of MRAM in the overlaying magnetoresistive memory layer 204. A transistor 304 is electrically connected to a sense current source, and a transistor 302 is electrically connected to a sense column select. These transistors 302, 304 and 306 can be electronic elements used for MRAM controller only, or also used for other memories and/or other logic circuit positioned in the substrate 202. In addition, the sense column select and sense current source can be used alone or together according to different designs.

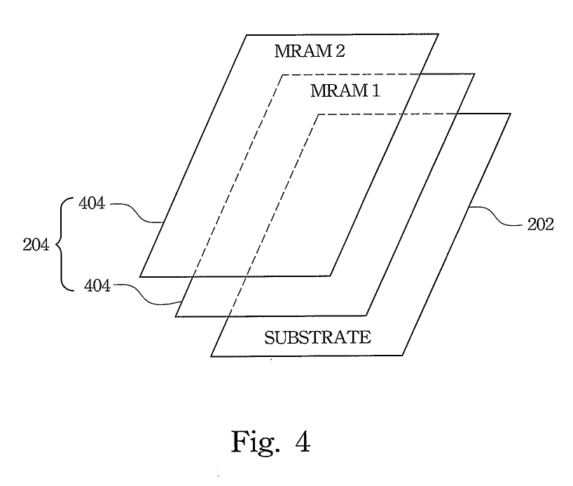

According to another embodiment of the present invention, the magnetoresistive memory layer 204 in FIG. 2A may comprise more than one layers stacked for enlarging the memory size. FIG. 4 illustrates a schematic view of one preferred embodiment, of which the magnetoresistive memory layer comprises more than one layers.

As illustrated in FIG. 4, the magnetoresistive memory layer 204 sits on top of the substrate 202. More particular, the magnetoresistive memory layer 204 comprises at least two layers 404. In this preferred embodiment, the layers 404 are stacked by back-end process with vias. A high density is obtained by this architecture having multiple stacked layers, and a very high yield is thus achieved.

For example, the substrate 202 comprises the underlying memory 214, the logic circuit 216 and the control circuit 212, the same as in FIG. 2A. The underlying memory 214 may be a DRAM-based memory, like PSRAM or LpSdram, with a smart virtual memory NAND FLASH adapter. As is well known in GMR MRAM technology, MRAM can be stacked with the underlying memory 214 with vias.

Since the cost of MRAM stack per wafer is almost fixed, NAND FLASH access features, FAT, FCB, and write history statistic can be optimized for storage in MRAM, and the NAND FLASH accessing over mobile memory also becomes much reliable by relying on the >10¹⁵ endurance capability of MRAM. Therefore, the optimization of the memory density and the logic circuit 216, such as a microprocessor, provide MRAM applications with all advantages in all mobile memory markets.

In conclusion, the single chip of the preferred embodiment has several advantages:

1. An n-substrate is omitted if no other memory is integrated in the single chip. In contrast to other embedded memories that require an n-substrate, MRAM is made up of metallic layers that sit on top of the p-substrate comprising logic circuits, such as memory control circuits. Higher yield and lower cost are achieved due to the reduced steps and chip fabrication complexity.

2. The single chip has a short manufacturing cycle. If the MRAM control circuit is integrated into the logic circuits of the chip by using back-end process, the only additional time required to completely build up the MRAM layers is less than 3 days during the preparation for manufacturing. Reducing cycle time leads to significantly lower overhead cost on the chip, lower work in process and shorter lead time to customers, and increases through put.

3. Minimum silicon area is required. The MRAM control circuit is integrated into the logic circuits of the substrate while the MRAM cells are stacked on top of the substrate. A smaller footprint of the resulting SOC allows more chips to be packed on a single wafer. Space available to embedded memory is also maximized.

4. Stackable MRAM layers are easily accomplished. To increase memory capacity, more than one MRAM layers can be added on the substrate to contain more MRAM cells. SOC generally needs a high memory density, and the additional layers can be added without sacrificing the die space. The memory density is thus increased at minimal cost.

5. MRAM can replace other memory, either volatile or non-volatile memory. MRAM combines the fast read/write characteristics of volatile memory and nonvolatile characteristics of non-volatile memory. The embedded MRAM can be used to replace all other embedded memory types used on the conventional SOC. By using a single MRAM, the memory management is simplified, and the cost of both design and manufacturing is decreased.

6. MRAM is compatible with various processes, such as CMOS, Bipolars, GaAs or other known suitable semiconductor processes.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A single chip having a magnetoresistive memory, comprising:
a substrate comprising an underlying memory and a control circuit; and
at least one magnetoresistive memory layer on the substrate, wherein the magnetoresistive memory layer comprises a plurality of magnetoresistive random access memory cells controlled by the control circuit.

2. The single chip of claim 1, wherein the underlying memory is a volatile or non-volatile memory.

3. The single chip of claim 2, wherein the volatile memory is DRAM or SRAM.

4. The single chip of claim 2, wherein the non-volatile memory is EPROM, EEPROM, FLASH or FeRAM.

5. The single chip of claim 1, wherein the substrate further comprises a microprocessor, a RFID circuit or an ASIC circuitry.

6. The single chip of claim 5, wherein the control circuit comprises a plurality of electronic elements, and some of the electronic elements are embedded in the microprocessor, a RFID circuit or an ASIC circuitry.

7. The single chip of claim 1, wherein the control circuit comprises a plurality of electronic elements.

8. The signal chip of claim 7, wherein some of the electronic elements are positioned within a region of the substrate.

9. The single chip of claim 1, wherein the magnetoresistive memory layer comprises multiple stacked layers.

10. The signal chip of claim 1, wherein the substrate is silicon or GaAs.

11. A single chip having magnetoresistive memory, comprising:
a substrate comprising a plurality of logic circuits and a control circuit; and
at least one magnetoresistive memory layer on the substrate, wherein the magnetoresistive memory layer comprises a plurality of magnetoresistive random access memory cells controlled by the control circuit.

12. The single chip of claim 11, wherein the substrate further comprises a volatile or non-volatile memory.

13. The single chip of claim 12, wherein the volatile is DRAM or SRAM.

14. The single chip of claim 12, wherein the non-volatile is EPROM, EEPROM, FLASH or FeRAM.

15. The single chip of claim 11, wherein the logic circuits comprise a microprocessor, a RFID circuit or an ASIC circuitry.

16. The single chip of claim 11, wherein the control circuit comprises a plurality of electronic elements.

17. The signal chip of claim 16, wherein some of the electronic elements are embedded in the logic circuits.

18. The signal chip of claim 16, wherein some of the electronic elements are positioned within a region of the substrate.

19. The single chip of claim 11, wherein the magnetoresistive memory layer comprises multiple stacked layers.

20. The signal chip of claim 11, wherein the substrate is silicon or GaAs.
